(19) United States
(12) Patent Application Publication
(10) Pub. No.: US 2014/0291679 A1
(43) Pub. Date: Oct. 2, 2014

(54) SEMICONDUCTOR DEVICE

(71) Applicant: Rohm Co., Ltd., Kyoto (JP)

(72) Inventor: Kiyotaka Umemoto, Kyoto (JP)

(73) Assignee: Rohm Co., Ltd., Kyoto (JP)

(21) Appl. No.: 14/226,945

(22) Filed: Mar. 27, 2014

(30) Foreign Application Priority Data
Mar. 29, 2013 (JP) 2013072290

(51) Int. Cl. H01L 21/66; G01R 31/26

(52) U.S. Cl. CPC H01L 22/32; G01R 31/2644
USPC 257/48

(57) ABSTRACT

A semiconductor device disclosed in the present specification comprises: a semiconductor chip, a package that incorporates the semiconductor chip, and a plurality of lower-surface pads disposed on a lower surface of the package, a plurality of upper-surface pads disposed on an upper surface of the package, wherein the plurality of upper-surface pads include a plurality of monitor pads each of which is connected to each of all the lower-surface pads.

### CROSS-REFERENCE TO RELATED APPLICATIONS

This application is based on the following Japanese application, the contents of which are hereby incorporated by reference.

(1) Patent application No.: 2013-072290 (the filing date: Mar. 29, 2013)

### BACKGROUND OF THE INVENTION

1. Field of the Invention

The present invention relates to a semiconductor device.

2. Description of Related Art

In recent years, a LSI [large scale integration] package is going leadless to reduce an area for mounting the package onto a printed wiring board. As an example of the leadless package, there are a BGA [ball grid array] package in FIG. 11 and a QFN [quad flat no lead package] package in FIG. 12.

In the meantime, as an example of the prior art relevant to the above description, there is JP-A-2011-187473.

However, a semiconductor device of the leadless package (especially, BGA package) has a problem that after being mounted on a printed wiring board, it is impossible to perform terminal monitoring (impossible to apply a probe to a pad).

In the meantime, as to the QFN package, it is possible to manage to perform the terminal monitoring from a side surface thereof. However, as to the QFN package, when mounting the package onto a printed wiring board, it is necessary to place a solder outside the package; accordingly, there is a problem that the mounting area is large compared to the BGA package.

### SUMMARY OF THE INVENTION

In light of the above problems found by the inventor of the present invention, it is an object of the present invention to provide a semiconductor device that is able to attain both reduction in the mounting area and achievement of the terminal monitoring function.

A semiconductor device disclosed in the present specification is structured to comprise: a semiconductor chip, a package that incorporates the semiconductor chip, a plurality of lower-surface pads disposed on a lower surface of the package, and a plurality of upper-surface pads disposed on an upper surface of the package, wherein the plurality of upper-surface pads include a plurality of monitor pads each of which is connected to each of all the lower-surface pads.

In the meantime, other features, elements, steps, advantages, and characteristics of the present invention will become more apparent from the following detailed description of preferred embodiments with reference to the attached drawings.

### DESCRIPTION OF THE DRAWINGS

FIG. 1 is a schematic view showing a basic structure of a semiconductor device.

FIG. 2 is a vertical cross-sectional view of a semiconductor device.

FIG. 3 is a schematic view showing a first embodiment of a semiconductor device.

FIG. 4 is a schematic view showing a second embodiment of a semiconductor device.

FIG. 5 is a schematic view showing a third embodiment of a semiconductor device.

FIG. 6 is a schematic view showing a fourth embodiment of a semiconductor device.

FIG. 7 is a vertical cross-sectional view showing a stack-mounting example of a semiconductor device.

FIG. 8 is a schematic view showing a first layout of a semiconductor chip.

FIG. 9 is a schematic view showing a second layout of a semiconductor chip.

FIG. 10 is an appearance view of a smart phone.

FIG. 11 is a schematic view showing a conventional example of a BGA package.

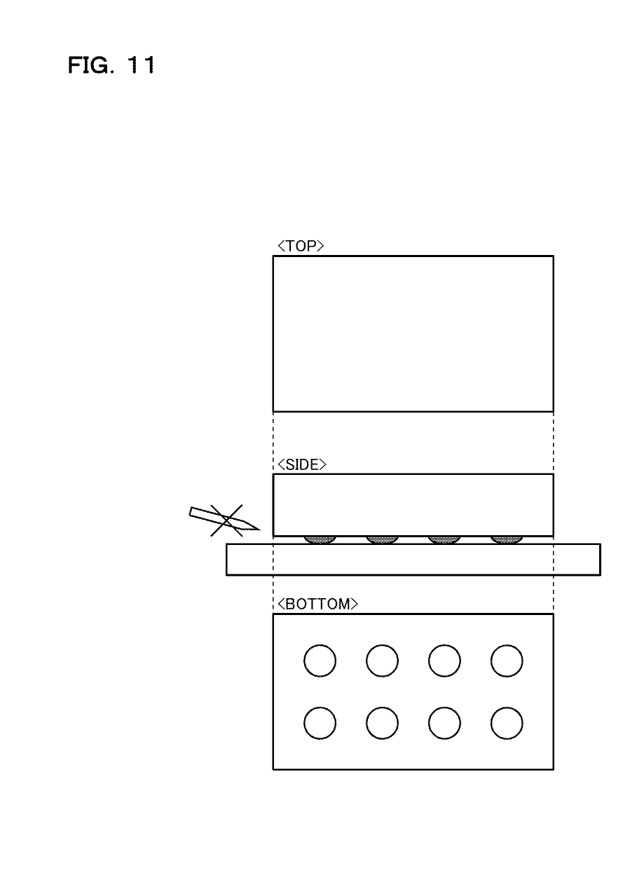

FIG. 12 is a schematic view showing a conventional example of a QFN package.

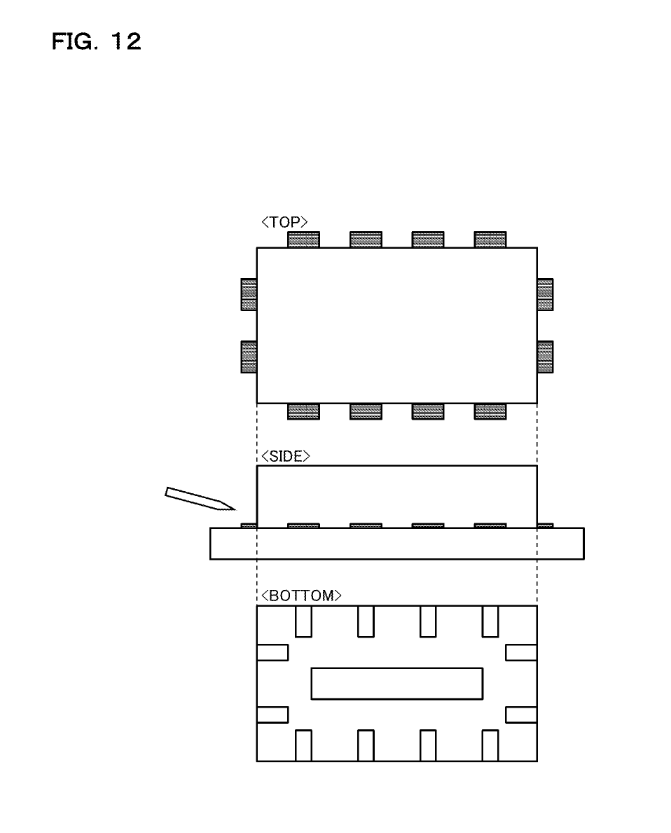

### DESCRIPTION OF PREFERRED EMBODIMENTS

### Basic Structure

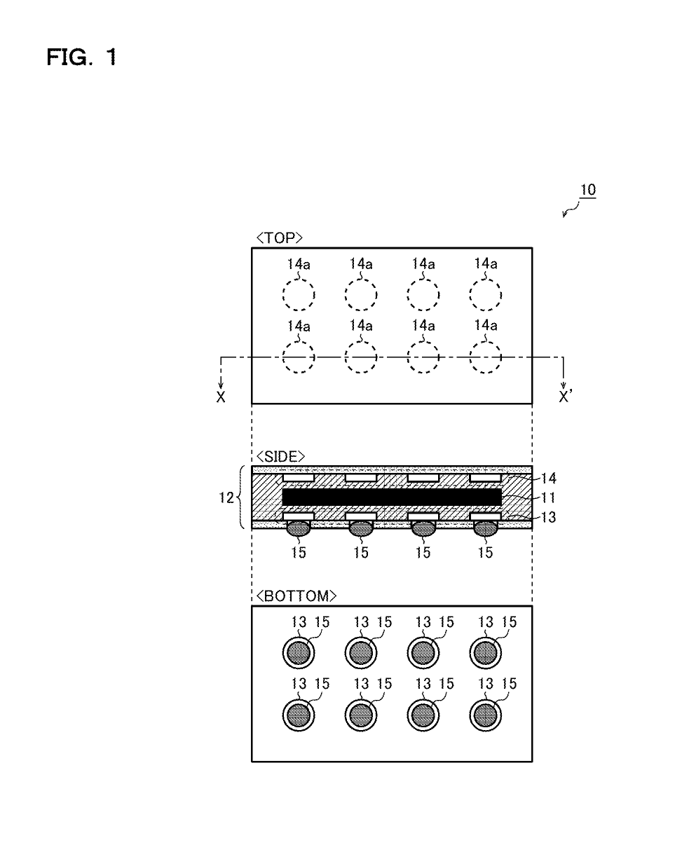

FIG. 1 is a schematic view showing a basic structure of a semiconductor device, and illustrates, from top in order, an upper surface view of a semiconductor device 10, a side surface view (X-X′ vertical cross-sectional view), and a lower surface view. The semiconductor device 10 in the present structural example has: a semiconductor chip 11; a leadless (BGA type) package 12 that incorporates the semiconductor chip 11; a plurality of lower-surface (BGA pads) pads 13 that are disposed on a lower surface (surface that opposes a printed wiring board (not shown) on which the semiconductor device 10 is mounted) of the package 12; a plurality of upper-surface pads 14 that are disposed on an upper surface of the package 12; and a plurality of solder bumps 15 each of which is connected to each of the plurality of lower-surface pads 13.

Here, the plurality of upper-surface pads 14 include a plurality of monitor pads 14a each of which is connected to each of all the lower-surface pads 13. It is possible to suitably form the monitor pad 14a by using a wiring layer and a via.

In other words, the semiconductor device 10 in the present structural example has a structure in which all the lower-surface pads 13 are pulled out as the monitor pad 14a to the upper surface of the package 12. According to such a structure, even after mounting of semiconductor device 10, it is possible to apply a probe to the monitor pad 14a to which the same voltage as a voltage applied to the lower-surface pad 13 is applied; accordingly, it becomes possible to easily perform terminal monitoring. Therefore, according to the semiconductor device 10 in the present structural example, it becomes possible to attain both reduction (employment of the BGA package) in the mounting area and achievement of the terminal monitoring function.

In the meantime, FIG. 1 illustrates, on the uppermost surface of the package 12, an insulating layer that covers the monitor pad 14a; however, the insulating layer is not always an essential structural component. This point is described in detail later with reference to a plurality of embodiments.

### Vertical Cross-Sectional View

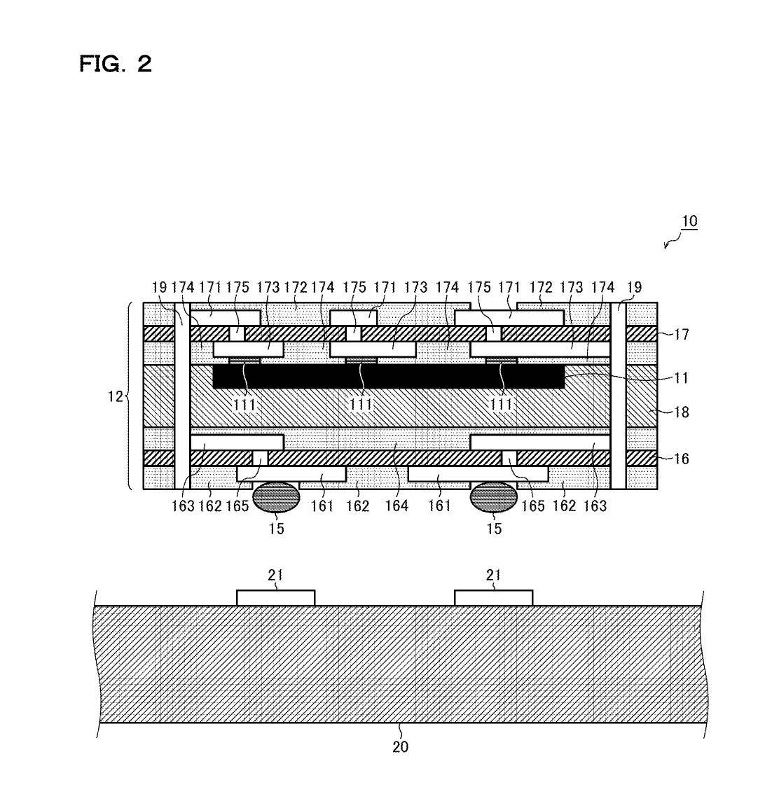

FIG. 2 is a vertical cross-sectional view of the semiconductor device 10. As shown in the drawing, the package 12 of the semiconductor device 10 incorporates the semiconductor chip 11, besides, includes a first substrate 16, a second substrate 17, a connecting member 18, and an electroconductive member 19.

A lower surface (side that opposes a printed wiring board 20 but does not oppose the second substrate 17) of the first substrate 16 is provided thereon with a first wiring layer 161 and a first insulating layer (solder resist layer) 162 that covers the first wiring layer 161. In the meantime, the above plurality of lower-surface pads 13 (see FIG. 1) are each formed by using the first wiring layer 161. In other words, the first insulating layer 162 is formed to cover the first wiring layer 161 except for a connecting region (region that functions as the lower-surface pad 13) of the solder bump 15.

An upper surface (side that opposes the second substrate 17) of the first substrate 16 is provide thereon with a second wiring layer 163 and a second insulating layer (solder resist layer) 164 that covers the second wiring layer.

Besides, the first substrate 16 is provide therethrough with a via 165 as an electroconductive route that connects electrically the first wiring layer 161 and the second wiring layer 163 to each other and penetrates both the upper and lower surfaces.

An upper surface (side that does not oppose the first substrate 16) is provided thereon with a third wiring layer 171 and a third insulating layer (solder resist layer) 172 that covers the third wiring layer 171. In the meantime, the above plurality of upper-surface pads 14 (see FIG. 1) are each formed by using the third wiring layer 171. However, of the plurality of upper-surface pads 14, the monitor pad 14a, to which a probe is applied during a terminal monitoring time only, does not always need to be exposed unlike the above lower-surface pad 13. Accordingly, the third insulating layer 172 may be formed to cover all the third wiring layers 171, or may be formed to expose a part of the third wiring layer 171 when necessary.

A lower surface (side that opposes the first substrate 16) of the second substrate 17 is provided thereon with a fourth wiring layer 173 and a fourth insulating layer (solder resist layer) 174 that covers the fourth wiring layer 173. In the meantime, the semiconductor chip 11 is mounted on the lower surface of the second substrate 17. Describing more specifically, the fourth insulating layer 174 is formed to expose a part of the fourth wiring layer 173, and the exposed part (chip connecting pad) and the semiconductor chip 11 are connected to each other by flip chip bonding by means of a solder bump 111. However, the semiconductor chip 11 may be mounted on the upper surface of the first substrate 16.

Besides, the second substrate 17 is provide therethrough with a via 175 as an electroconductive route that connects electrically the third wiring layer 171 and the fourth wiring layer 173 to each other and penetrates both the upper and lower surfaces.

The connecting member 18 is an adhesive that has an electric insulating characteristic and connects the upper surface of the first substrate 16 and the lower surface of the second substrate 17 with them opposing each other.

The electroconductive member 19 is a penetrating via that connects electrically the first substrate 16 and the second substrate 17 to each other. When looking at the first substrate 16, the electroconductive member 19 is connected to at least one of the first wiring layer 161 and the second wiring layer 163. Besides, when looking at the second substrate 17, the electroconductive member 19 is connected to at least one of the third wiring layer 171 and the fourth wiring layer 173. In the meantime, the electroconductive member 19 may be formed to penetrate the both upper and lower surfaces of the package 12 after attaching the first substrate 16 and the second substrate 17 to each other by means of the connecting member 18. As described above, one end of the electroconductive member 19 is pulled out to the upper surface of the package 12; accordingly, of the plurality of electroconductive members 19, the electroconductive member connected to the lower-surface pad 13 is also usable as the monitor pad 14a.

The semiconductor device 10 having the above structure is connected to a wiring layer 21 of the printed wiring board 20 by flip chip bonding via the plurality of solder bumps 15. Such semiconductor device 10 of the leadless package can contribute to size reduction and thickness reduction of an electronic apparatus that uses the above semiconductor device 10.

### FIRST EMBODIMENT

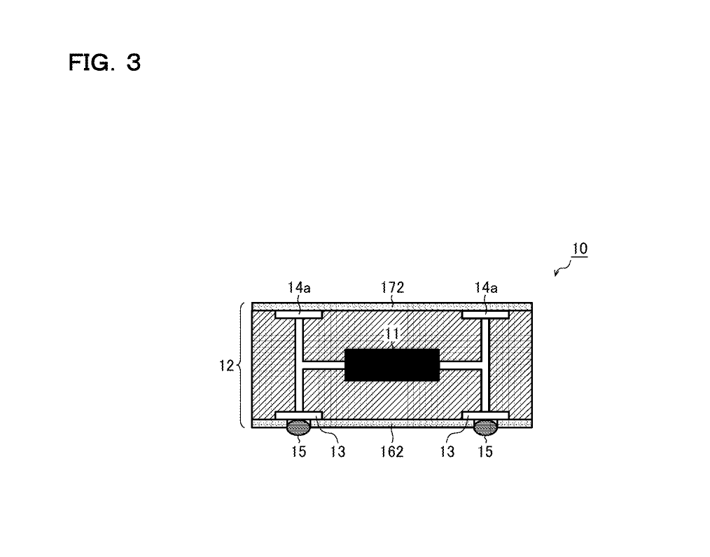

FIG. 3 is a schematic view showing a first embodiment of the semiconductor device 10. In the first embodiment, the upper surface of the package 12 is provided with only the plurality of monitor pads 14a that are connected, one to one, to the plurality of lower-surface pads 13. Bedsides, in the first embodiment, the uppermost surface of the package 12 is provided with the insulating layer 172 (corresponding to the third insulating layer 172 of FIG. 2) that covers the plurality of monitor pads 14a. By employing such a structure, it is possible to prevent an unintentional short and the like of the monitor pad 14a. In the meantime, when performing the terminal monitoring, by suitably peeling off the insulating layer 172, the monitor pad 14a to which the probe is to be applied is exposed.

### SECOND EMBODIMENT

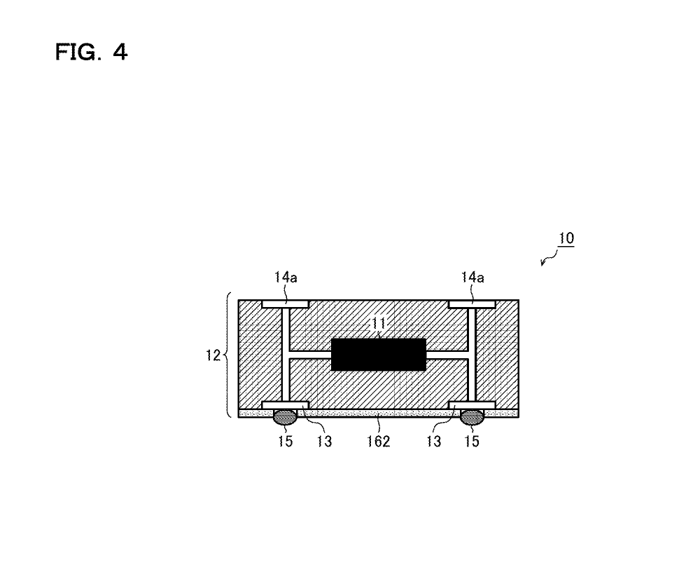

FIG. 4 is a schematic view showing a second embodiment of the semiconductor device 10. The second embodiment is a modification of the first embodiment (FIG. 3) and has a structure in which the insulating layer 172 is not used and the plurality of monitor pads 14a are originally exposed. By employing such a structure, the work of peeling off the insulating layer 172 during the terminal monitoring time becomes unnecessary; accordingly, it is possible to perform the terminal monitoring more easily. Besides, according to the second embodiment, it becomes also possible to simplify a production process of the semiconductor device 10 (especially, second substrate 17).

### THIRD EMBODIMENT

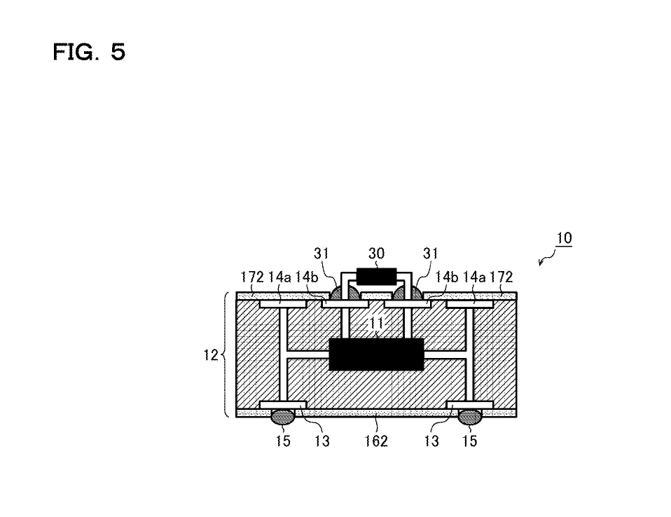

FIG. 5 is a schematic view showing a third embodiment of the semiconductor device 10. In the third embodiment, the upper surface of the package 12 is provided with not only the monitor pad 14a but also a component mounting pad 14b for mounting an external component 30 (resistor, capacitor and the like). As to the external component 30, its terminal portion is fixed to the component mounting pad 14b by using a solder 31. By employing such a structure, it is possible to mount both the semiconductor device 10 and the external component 30 by means of only the mounting area for the semiconductor device 10; accordingly, it becomes possible to achieve size reduction of the printed wiring board 20 (see FIG. 2). In the meantime, the component mounting pad 14a connects electrically the semiconductor chip 11 and the external component 30 to each other, but is not always connected to the lower-surface pad 13.

### FOURTH EMBODIMENT

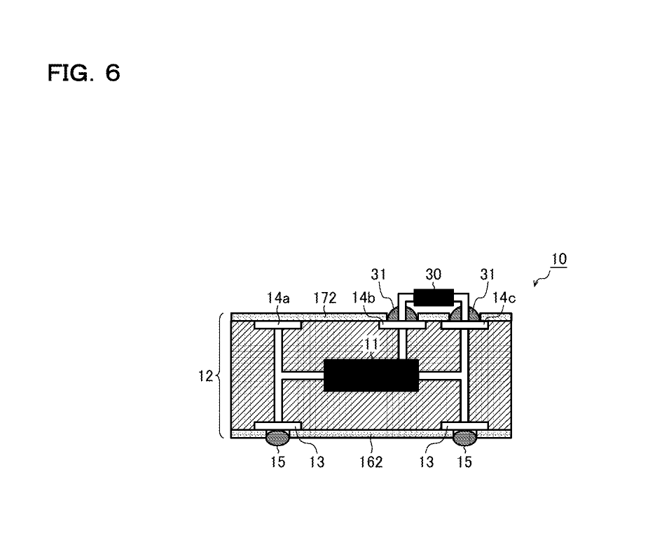

FIG. 6 is a schematic view showing a fourth embodiment of the semiconductor device 10. In the fourth embodiment, at least one of the plurality of monitor pads 14a doubles as the component mounting pad 14b. In FIG. 6, a both-use pad 14c is the monitor pad and electrically connected to the lower-surface pad 13 while being used for the mounting of the external component 30. By employing such a structure, it becomes possible to achieve both the terminal monitoring function and the component mounting function without unnecessarily increasing the number of upper-surface pads 14.

### Stack Mounting

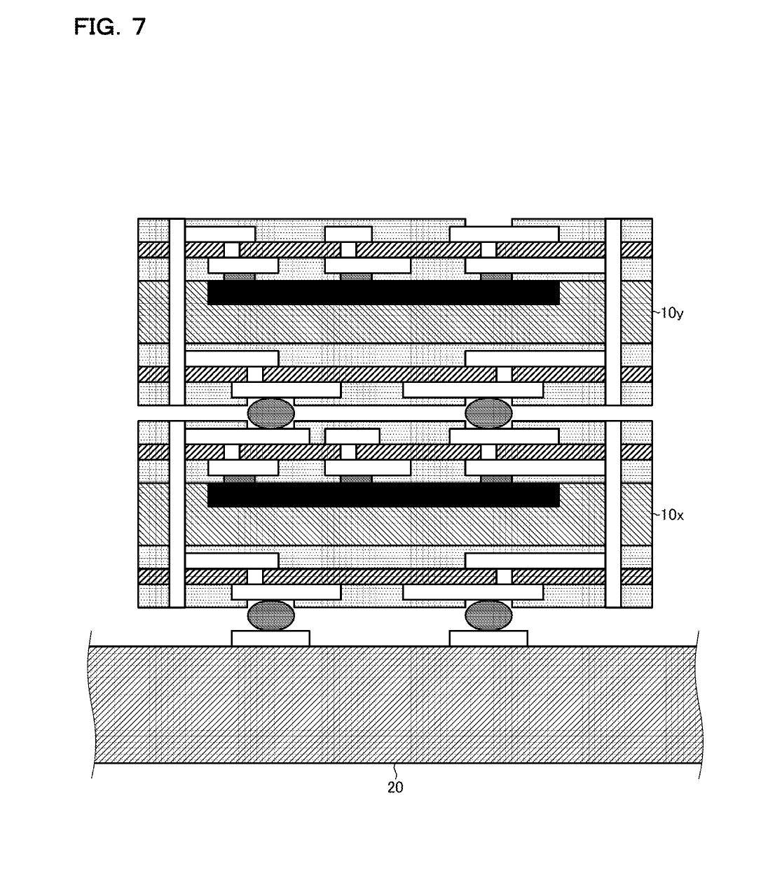

FIG. 7 is a vertical cross-sectional view showing a stack-mounting example of the semiconductor device 10. As shown in the drawing, it is also possible to prepare a plurality of semiconductor devices 10x and 10y and stack-mount these onto the printed wiring board 20. By employing such a structure, it is possible to mount the plurality of semiconductor devices 10x and 10y by means of the mounting area for only one semiconductor device; accordingly, it becomes possible to achieve the size reduction of the printed wiring board 20. In the meantime, if the above semiconductor device 10 (see FIG. FIG. 1 to FIG. 6) is used as the semiconductor devices 10x and 10y, it becomes possible to perform the terminal monitoring of both the semiconductor devices 10x and 10y by using the monitor pad 14a for the semiconductor device 10y.

### Chip Layout

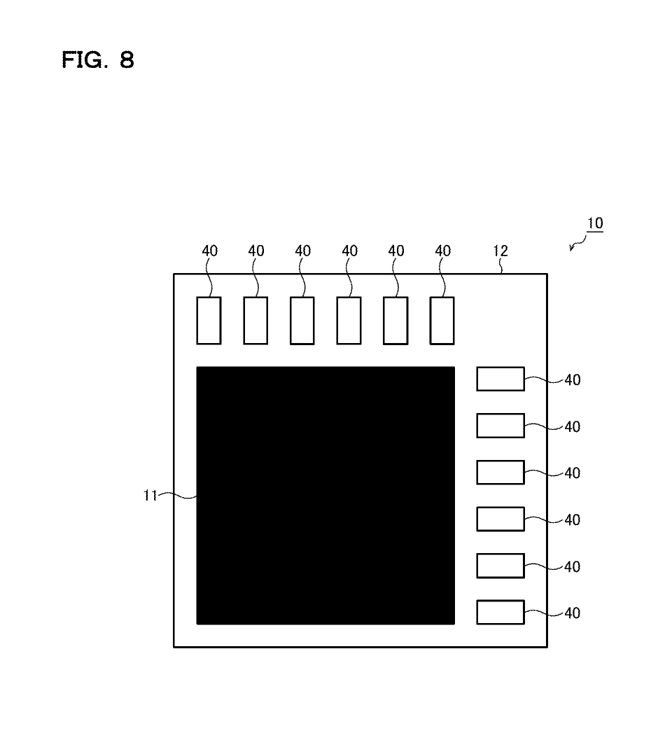

FIG. 8 is a schematic view (plan view) showing a first layout of the semiconductor chip 11. In the first layout, when viewing from top, the rectangular semiconductor chip 11 is disposed such that each edge becomes parallel to each edge of the package 12 that is rectangular alike. In the case where the first layout is employed, to increase area efficiency when incorporating the semiconductor chip 11 and a plurality of peripheral components 40 connected to the semiconductor chip into one package 12, the semiconductor chip 11 is placed near one corner of the package 12, and the plurality of peripheral components 40 are arranged and disposed to oppose two edges of the semiconductor chip 11.

However, in the first layout, in the case where it is attempted to connect the semiconductor chip 11 and the plurality of peripheral components 40 to each other over the shortest distance, peripheral component connecting pads must be integrated on only two of the four edges of the semiconductor chip 11 that oppose the plurality of peripheral components 40, so that there is a problem that the pad layout of the semiconductor chip 11 is restricted. On the other hand, in the first layout, in the case where the peripheral component connecting pads are disposed on all the four edges of the semiconductor chip 11, wiring patterns are arranged from the plurality of peripheral components 40 for the two edges of the four edges of the semiconductor chip 11 that do not oppose the plurality of peripheral components 40; accordingly, there is a problem that a disposition area for the wiring patterns increases, besides, signal delay and superposed noise easily occur.

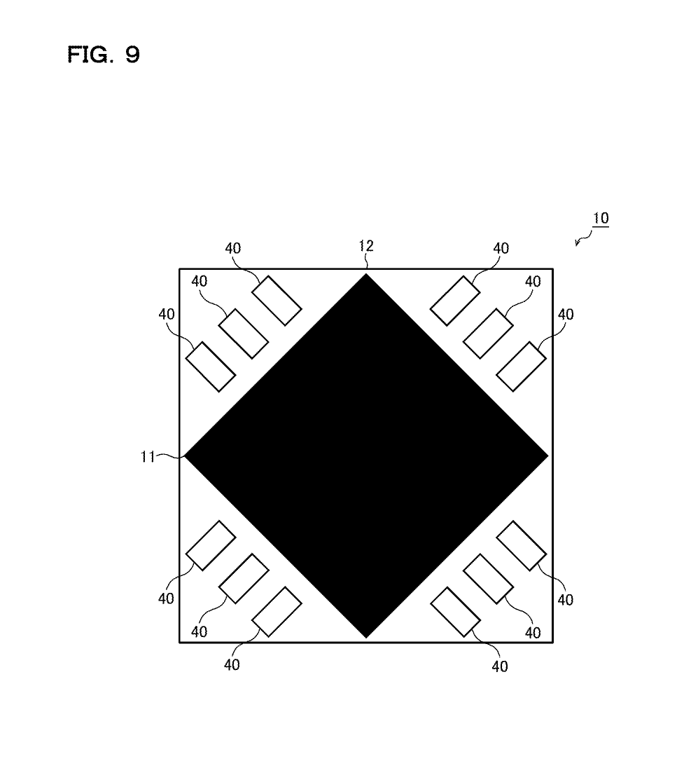

FIG. 9 is a schematic view (plan view) showing a second layout of the semiconductor chip 11. The semiconductor chip 11 is rotated by a predetermined angle (e.g., 45 degrees) in a planar manner with respect to the package 12 and incorporated. By employing the second layout, it is possible to equally divide and dispose the plurality of peripheral components 40 to oppose the four edges of the semiconductor chip 11; accordingly, it becomes possible to connect the semiconductor chip 11 and the plurality of peripheral components 40 to each other over the shortest distance with no restrictions occurring on the pad layout of the semiconductor chip 11.

### Application to Electronic Apparatus

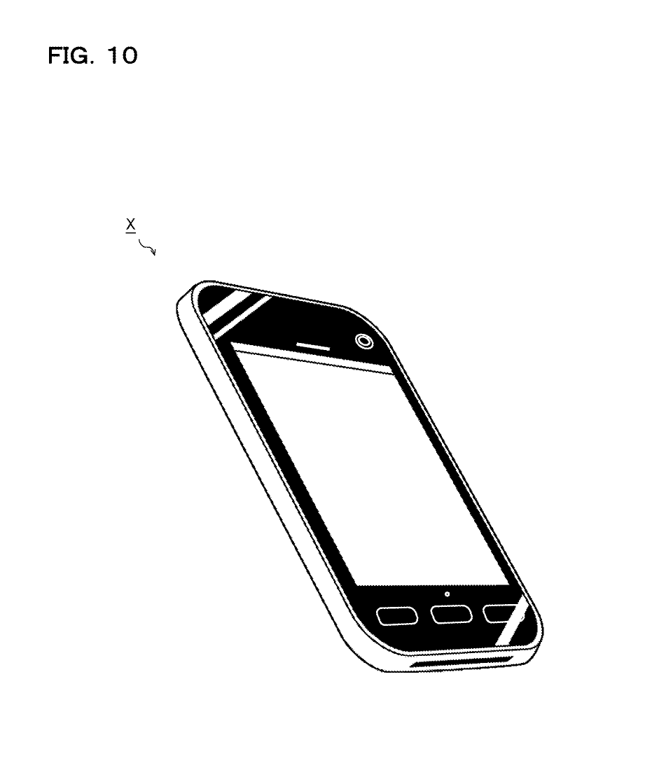

FIG. 10 is an appearance view of a smart phone. A smart phone X is an example of an electronic apparatus in which the semiconductor device 10 is mounted. The smart phone X is a product for which not only size reduction and thickness reduction but also high reliability is required. Accordingly, it is sayable that the semiconductor device 10 of the leadless package, which allows the terminal monitoring, is very suitable for the mounting into the smart phone X.

### Other Modifications

In the meantime, in the above embodiments, the semiconductor device of the BGA package is described as an example; however, the application target of the present invention is not limited to this, and also a semiconductor device of a leadless package (LGA package, PGA package and the like) that employs another structure can become an application target of the present invention.

As described above, the various technical features disclosed in the present specification are able to be modified without departing from the spirit of the technical creation besides the above embodiments. In other words, it should be considered that the above embodiments are examples in all respects and are not limiting, and it should be understood that the technical scope of the present invention is not indicated by the above description of the embodiments but by the claims, and all modifications within the scope of the claims and the meaning equivalent to the claims are covered.

### INDUSTRIAL APPLICABILITY

The present invention is usable for mobile apparatuses such as a smart phone and the like.

What is claimed is:

1. A semiconductor device comprising:
a semiconductor chip,
a package that incorporates the semiconductor chip,
a plurality of lower-surface pads disposed on a lower surface of the package, and
a plurality of upper-surface pads disposed on an upper surface of the package,
wherein the plurality of upper-surface pads include a plurality of monitor pads each of which is connected to each of all the lower-surface pads.

2. The semiconductor device according to claim 1, further comprising an insulating layer that covers the plurality of monitor pads.

3. The semiconductor device according to claim 1, wherein the plurality of upper-surface pads include a component mounting pad for mounting an external component.

4. The semiconductor device according to claim 3, wherein at least one of the plurality of monitor pads doubles as the component mounting pad.

5. The semiconductor device according to claim 1, wherein the package includes:
a first substrate on a lower surface of which the plurality of lower-surface pads are formed,
a second substrate on an upper surface of which the plurality of upper-surface pads are formed,
a connecting member that connects an upper surface of the first substrate and a lower surface of the second substrate to each other with the upper surface and the lower surface opposing each other, and
an electroconductive member that connects electrically the first substrate and the second substrate to each other.

6. The semiconductor device according to claim 5, wherein
the semiconductor chip is mounted on the lower surface of the second substrate or the upper surface of the first substrate.

7. The semiconductor device according to claim 1, wherein
the semiconductor chip is incorporated with rotated in a planar manner with respect to the package.

8. The semiconductor device according to claim 1, wherein
the package is of a BGA [ball grid array] type, LGA [land grid array] type, or a PGA [pin grid array] type.

9. An electronic apparatus comprising:
a printed wiring board, and
the semiconductor device according to claim 1 mounted on the printed wiring board.

10. The electronic apparatus according to claim 9, wherein
the semiconductor device is stack-mounted.

11. The semiconductor device according to claim 2, wherein
the plurality of upper-surface pads include a component mounting pad for mounting an external component.

12. The semiconductor device according to claim 11, wherein
at least one of the plurality of monitor pads doubles as the component mounting pad.

13. The semiconductor device according to claim 2, wherein the package includes:
a first substrate on a lower surface of which the plurality of lower-surface pads are formed,
a second substrate on an upper surface of which the plurality of upper-surface pads are formed,
a connecting member that connects an upper surface of the first substrate and a lower surface of the second substrate to each other with the upper surface and the lower surface opposing each other, and
an electroconductive member that connects electrically the first substrate and the second substrate to each other.

14. The semiconductor device according to claim 3, wherein the package includes:
a first substrate on a lower surface of which the plurality of lower-surface pads are formed,
a second substrate on an upper surface of which the plurality of upper-surface pads are formed,
a connecting member that connects an upper surface of the first substrate and a lower surface of the second substrate to each other with the upper surface and the lower surface opposing each other, and
an electroconductive member that connects electrically the first substrate and the second substrate to each other.

15. The semiconductor device according to claim 4, wherein the package includes:
a first substrate on a lower surface of which the plurality of lower-surface pads are formed,
a second substrate on an upper surface of which the plurality of upper-surface pads are formed,
a connecting member that connects an upper surface of the first substrate and a lower surface of the second substrate to each other with the upper surface and the lower surface opposing each other, and
an electroconductive member that connects electrically the first substrate and the second substrate to each other.
